(19) United States
(12) Patent Application Publication
(10) Pub. No.: US 2011/0197954 A1
(43) Pub. Date: Aug. 18, 2011

(54) PHOTOVOLTAIC APPARATUS AND PHOTOVOLTAIC ARRAY ATTACHED TO A SUPPORT STRUCTURE

(75) Inventors: James R. Young, Dearborn, MI (US); Thomas J. Denniston, Temperance, MI (US)

(73) Assignee: Xunlight Corporation, Toledo, OH (US)

(21) Appl. No.: 13/027,016

(22) Filed: Feb. 14, 2011

Related U.S. Application Data
(60) Provisional application No. 61/304,518, filed on Feb. 15, 2010.

(51) Int. Cl. H01L 31/048; H01L 31/02; H01L 31/05

(52) U.S. Cl. 136/251; 136/252

(57) ABSTRACT

A photovoltaic apparatus is provided. The photovoltaic apparatus includes a photovoltaic module. The photovoltaic apparatus also includes at least one support strip attached to a bottom surface of the photovoltaic module. Each support strip has a first edge portion, a center portion, and a second edge portion. The second edge portion includes a flange having a first end and a second end. A photovoltaic array is also provided. The photovoltaic array includes a first photovoltaic apparatus and a second photovoltaic apparatus. The photovoltaic array is attached to a support structure.

### RELATED APPLICATION

This application is claiming the benefit, under 35 U.S.C. 119(e), of the provisional application which was granted Ser. No. 61/304,518 filed on Feb. 15, 2010 under 35 U.S.C. 111(b). The provisional application is hereby incorporated by reference.

### BACKGROUND OF THE INVENTION

This invention relates generally to flexible photovoltaic (PV) modules, and more specifically to a PV apparatus and an array of PV modules attached to a support structure.

PV cells can be produced by forming PV semiconductor materials, such as thin-film silicon based amorphous silicon (a-Si), on low-cost flexible substrates such as stainless steel or plastic. A flexible PV module may be constructed by electrically connecting one or more of the flexible PV cells in series and encapsulating the cells between protective layers. Generally, the PV module has a top (facing the sun) protective layer and a bottom protective layer. For flexible PV modules, the top and bottom layers may be thin sheets of a polymeric material. The bottom layer polymeric sheet is usually referred to as a back sheet.

Typically, flexible PV modules are installed by directly attaching the module back sheet to a surface. Traditional surfaces for attaching flexible PV modules to are commercial and residential rooftops. Generally, these surfaces are flat and provide a maximum amount of supporting contact area. However, installation on uneven surfaces such as corrugated rooftops or irregular surfaces can be problematic because of the reduction in supporting contact area between the bottom layer of the PV module and the surface. Therefore, a need exists for an apparatus which allows flexible PV modules to be attached too both even and uneven surfaces and remain in a substantially planar orientation after installation.

### SUMMARY OF THE INVENTION

The present invention is directed to a photovoltaic apparatus. A photovoltaic array which may be attached to a support structure is also provided.

The photovoltaic apparatus comprises a photovoltaic module and at least one support strip attached to a bottom surface of the photovoltaic module. Each support strip comprises a first edge portion, a center portion, and a second edge portion. The second edge portion includes a flange having a first end and a second end.

The photovoltaic array comprises a first flexible photovoltaic module and a first support strip and a second support strip attached to opposite sides of and spaced apart on a bottom surface of the first flexible photovoltaic module. The support strips comprise a first edge portion, a center portion, and a second edge portion. The photovoltaic array also comprises a second flexible photovoltaic module and a first support strip and a second support strip attached to opposite sides of and spaced apart on a bottom surface of the second flexible photovoltaic module. The support strips comprising a first edge portion, a center portion, and a second edge portion. Additionally, the second support strip attached to the first flexible photovoltaic module is attached to the first support strip attached to the second flexible photovoltaic module.

The photovoltaic array may be attached to a support structure. In certain embodiments, the support structure is a corrugated rooftop.

### BRIEF DESCRIPTION OF THE DRAWINGS

FIG. 1 is a perspective view of a photovoltaic array of the present invention;

FIG. 2 is a perspective view of a photovoltaic array of the present invention;

FIG. 3 is a cross-sectional view of a first embodiment of the photovoltaic array of FIG. 1 taken along the line 3-3;

FIG. 4 is cross-sectional view of a second embodiment of the photovoltaic array of FIG. 1;

FIG. 5 is cross-sectional view of a third embodiment of the of the photovoltaic array of FIG. 1;

FIG. 6 is a cross-sectional view of a fourth embodiment of the of the photovoltaic array of FIG. 1;

FIG. 7 is a cross-sectional view of a fifth embodiment of the photovoltaic array of FIG. 1;

FIG. 8 is a cross-sectional view of a sixth embodiment of the photovoltaic array of FIG. 1;

FIG. 9 is a cross-sectional view of a seventh embodiment of the photovoltaic array of FIG. 1;

FIG. 10 is a cross-sectional view of an embodiment of the photovoltaic array of FIG. 2 taken along the line 10-10;

FIG. 11 is a partial perspective view of a photovoltaic array of the present invention; and

FIG. 12 is a partial perspective view of an embodiment of the photovoltaic array of FIG. 11.

### DETAILED DESCRIPTION OF THE PREFERRED EMBODIMENT(S)

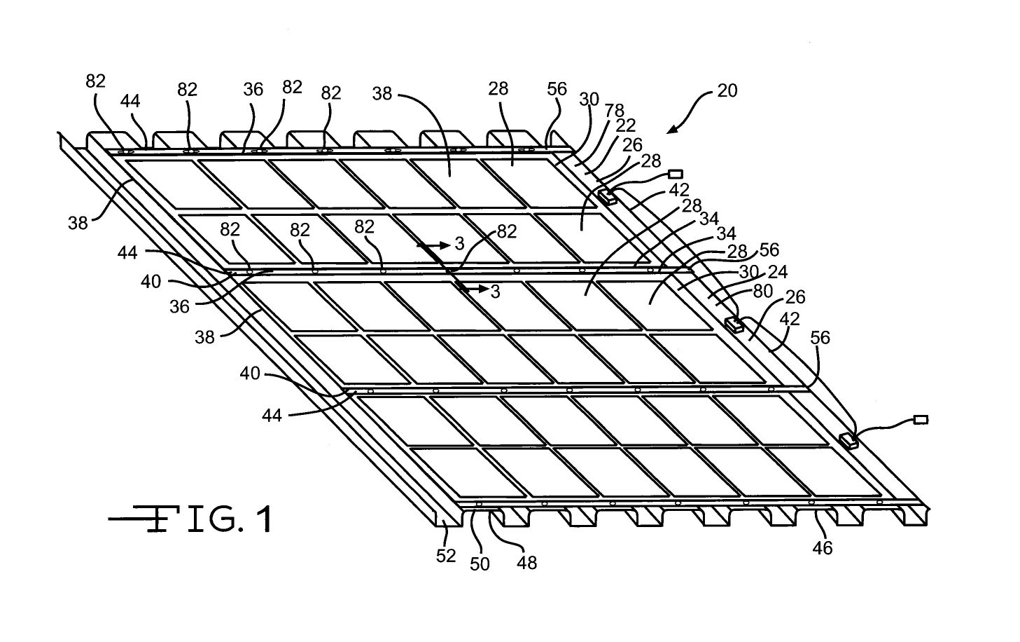

It is to be understood that the invention may assume various alternative orientations and step sequences, except where expressly stated to the contrary. It should also be appreciated that the embodiments described and structures illustrated in FIGS. 1-12 and described in the following specification are simply exemplary embodiments of the inventive concepts defined in the appended claims. For example, although the present invention will be described in connection with PV modules having at least one PV cell having a single junction of a-Si or a triple junction of a-Si the present invention is not so limited. As such, the present invention may also include PV cells having at least one single junction of cadmium telluride (CdTe), amorphous silicon germanium (a-SiGe), crystalline silicon (c-Si), microcrystalline silicon (mc-Si), nanocrystalline silicon (nc-Si), CIS, CIGS, or CIGSe.

FIGS. 1, 2, 11 depict embodiments of the PV array 20 and PV apparatuses 22, 24 of the present invention. FIGS. 3-10 and 12 depict embodiments of portions of the PV array 20 and PV apparatuses 22, 24 of the present invention.

The PV array 20 comprises at least a first PV apparatus 22 and a second PV apparatus 24. However, it should be appreciated that the PV array 20 may comprise many more than two PV apparatuses. It should also be appreciated that two smaller PV arrays can be mechanically and electrically connected to form a larger PV array.

Each PV apparatus 22, 24 comprises a PV module 26. Each PV module 26 includes a plurality of electrically connected PV cells 28. In an embodiment, the PV modules 26 are flexible. For example, the PV modules 26 may be an XR-12 or an XR-36 sold by the Xunlight Corporation.

Each PV module 26 includes a transparent top surface 30, a bottom surface 32, and a perimeter 34. The transparent top surface 30 prevents corrosion of the PV cells 28 while allowing for high light transmission. Preferably, the transparent top surface 30 is composed of ETFE, EVA, or a combination thereof. The bottom surface 32 may include a back sheet. The back sheet may be a multi-layer laminate. The back sheet provides moisture protection, UV stability, and weatherability. In an embodiment, the back sheet comprises a fluoropolymer.

Both the PV module top surface 30 and bottom surface 32 include a first edge 36, a second edge 38, a third edge 40, and a fourth edge 42. The first edge 36, second edge 38, third edge 40, and fourth edge 42 form the PV module perimeter 34.

Each PV apparatus 22, 24 comprises at least one support strip 44, preferably two. The at least one support strip 44 can be utilized to attach the PV apparatuses 22, 24 to each other, at least one other adjacent PV apparatus, and/or a support structure 46.

Preferably, each PV apparatus 22, 24 and PV array 20 is positioned above and fixedly attached to the support structure 46. The support structure 46 can comprise a smooth contiguous surface, an uneven surface, or a combination thereof. When the support structure 46 includes an uneven surface, the support strips 44 provide support along edges of the PV module 26, preferably along their longitudinal edges, so that the PV modules 26 remains in a substantially planar orientation. In this manner, the support strips 44 prevent portions of the PV modules 26 from sagging into or conforming to the topography of the uneven surface. In certain embodiments, the support structure 46 may be a corrugated rooftop 48.

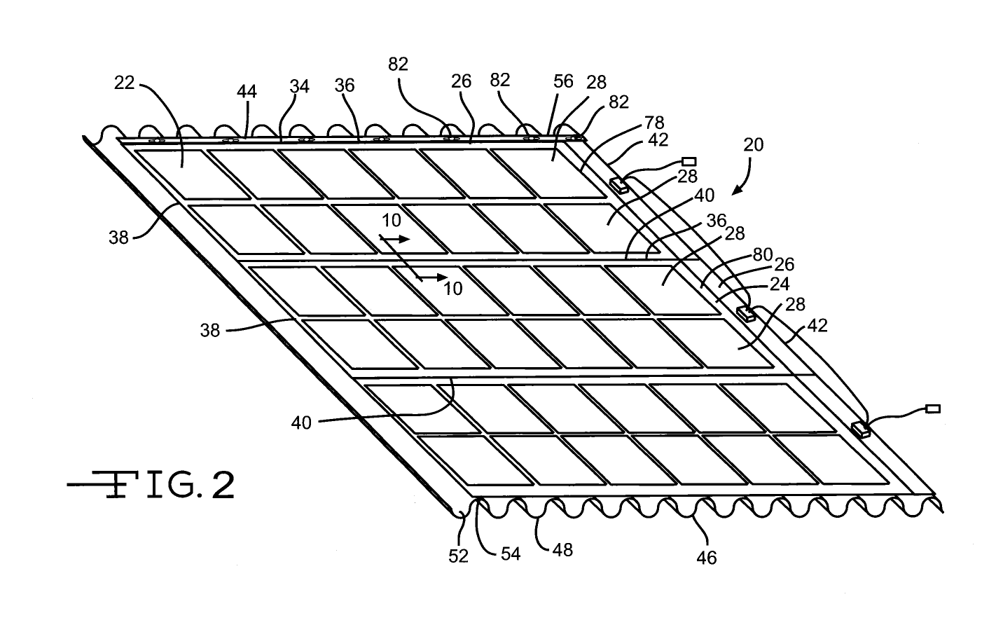

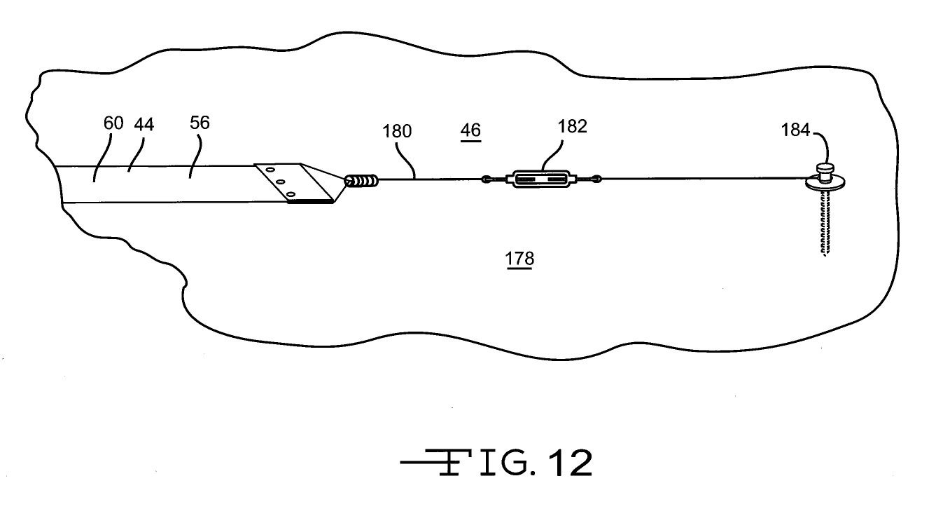

Corrugated rooftops 48 suitable for practicing the present invention may be configured in many ways. For example, in an embodiment like the one shown in FIG. 1, the corrugated rooftop 48 may have a repeating pattern of plateaus 50 and valleys 52. In another embodiment, like the one depicted in FIG. 2, the corrugated rooftop 48 may have a repeating pattern of peaks 54 and valleys 52. Those skilled in the art would appreciate that other corrugated rooftop configurations may be utilized in practicing the present invention. Additionally, as shown in FIGS. 11-12, in other embodiments the support structure 46 may not be a rooftop. In these embodiments, the support structure 46 may be a combination of earthen surface and mounting rails (not depicted). In certain embodiments, the mounting rails are configured in a manner similar to the plateaus 50 and/or peaks 54 of the corrugated rooftop 48 embodiments described, above.

Preferably, each support strip 44 is at least partially resistant to corrosion caused by water or atmospheric gases. In an embodiment, the support strips 44 are at least semi-rigid. In another embodiment, the support strips 44 are rigid. In these embodiments, the support strips 44 may be metallic, plastic, or a combination thereof. In an embodiment, each support strip 44 is composed of a metal or a metal alloy material. For example, aluminum or galvanized aluminum may be utilized as support strip materials. In another embodiment, each support strip 44 is composed of rigid PVC, i.e. PVC containing very little plasticizer. In yet another embodiment, each support strip 44 is composed of aluminum and coated with rigid PVC. Preferably, the PV module bottom surface 32 is composed of a material that is different than the material utilized for the support strips 44.

In certain embodiments, the PV apparatuses 22, 24, which include the at least one support strip 44, comprise a first support strip 56 and a second support strip 58. The first support strip 56 and second support strip 58 are configured as described, above. The first support strip 56 and second support strip 58 are attached to opposite sides of and are spaced apart on the bottom surface 32 of the PV module 26. Thus, the first support strip 56 is a separate body from the second support strip 58. In this manner, the use of support strip materials and PV array costs are minimized.

As shown in FIG. 3, the first support strip 56 and second support strip 58 each have a first surface 60 and a second surface 62. The support strip first surface 60 is attached to the PV module bottom surface 32. The support strip second surface 62 may be attached to the support structure 46.

The support strips 56, 58 are preferably attached to the PV module bottom surface 32 with an adhesive 64 and more preferably a water resistant adhesive. In an embodiment, the adhesive 64 comprises a butyl adhesive or a butyl adhesive tape. However, other water resistant adhesives may be utilized. For example, acrylic, polyurethane, or a modified silicone adhesive may be utilized to attach the support strips 56, 58 to the PV module bottom surface 32. A primer may be used with the adhesive 64 to enhance the bond between the support strips 56, 58 and the PV module bottom surface 32. Those skilled in the art should appreciate that the support strips 56, 58 may also be attached to the PV module bottom surface 32 mechanically. Preferably, each support strip 56, 58 is attached to the PV module 26 after the PV module 26 is formed. As such, the support strips 56, 58 and the PV module 26 may not form a unitary body.

Each support strip 56, 58 extends substantially along an edge 36, 38, 40, 42 of the PV module 26 it is attached to. Preferably, the support strips 56, 58 extend along the longitudinal edges of the PV module 26. Thus, in an embodiment, the support strips 56, 58 are attached to and extend along the first edge 36 and third edge 40 of each PV module 26.

Each support strip first surface 60 and second surface 62 comprise a first edge portion 66, a center portion 68, and a second edge portion 70. The first edge portion 66 and center portion 68 of the first surface 60 of each support strip 56, 58 are attached to the bottom surface 32 of the PV module 26. Generally, the support strip second edge portion 70 extends beyond the perimeter 34 of the PV module 26 it is attached to. The support strip second edge portion 70 includes a flange 72. Each flange 72 has a first end 74 and a second end 76.

In an embodiment, at least one support strip 56, 58 extends beyond an edge 36, 38, 40, 42 of the PV module perimeter 34. In another embodiment, both support strips 56, 58 extend beyond two opposite edges 36, 40 of the PV module perimeter 34. Preferably, the support strip flange 72 extends beyond the perimeter 34 of the PV module 26. Alternatively, it should be appreciated that the first and second support strips 56, 58 may be attached to and extend beyond the second edge 38 and fourth edge 42 of each PV module 26.

As stated, an embodiment of the PV array 20 is depicted in FIG. 1. The PV array 20 comprises the first and second PV apparatuses 22, 24 as described, above. The first PV apparatus 22 and the second PV apparatus 24 are configured as described, above. The first PV apparatus 22 comprises the first support strip 56 and the second support strip 58 as described, above. The first support strip 56 and the second support strip 58 are attached to opposite sides of and spaced apart on the bottom surface 32 of a first PV module 78. The second PV apparatus 24 comprises a second PV module 80. The first and second PV modules 78, 80 may be flexible PV modules 26 and configured as described, above. The second PV apparatus 24 also comprises the first support strip 56 and the second support strip 58 attached to opposite sides of and spaced apart on the bottom surface 32 of the second PV module 80. As shown best in FIG. 1, the first support strip 56 attached to the first PV module 78 is attached to the support structure 46. In this embodiment the support structure 46 is a corrugated roof 48.

As shown in the embodiments depicted in FIGS. 3-5, the second support strip 58 attached to the first PV module 78 is attached to the first support strip 56 attached to the second PV module 80 and the support structure 46. In these embodiments, the flanges 72 are substantially planar. In the embodiment depicted in FIG. 3, the flange 72 of the first support strip 56 attached to the second PV module 80 is positioned over the flange 72 of the second support strip 58 attached to the first PV module 78. In the alternative embodiment shown in FIG. 5, the flange 72 of the second support strip 56 attached to the first PV module 78 may be positioned over the flange 72 of the first support strip 56 attached to the second PV module 80. In these embodiments, the flanges 72 overlap so that the first end 74 of the flange 72 of the second support strip 58 is located above the second end 76 of the flange 72 of the first support strip 56 of the first PV module 78 or vice versa.

Referring back to FIG. 1, a plurality of fasteners 82, such as nails or screws, may be positioned along the length of the PV array 20. The fasteners 82 may be provided to attach the support strips 56, 58 together, attach a support strip 56, 58 to the support structure 46, and/or fixedly position the PV array 20 above the support structure 46. As depicted in FIGS. 3 and 5, in certain embodiments, each fastener 82 extends through the flanges 72 and into the support structure 46. In this embodiment, the fasteners 82 are positioned between the first end 74 and the second end 76 of each flange 72. Additionally, the fasteners 82 may extend through an aperture 84 in each support strip 56, 58 and the support structure 46. In an embodiment, the apertures 84 are preformed.

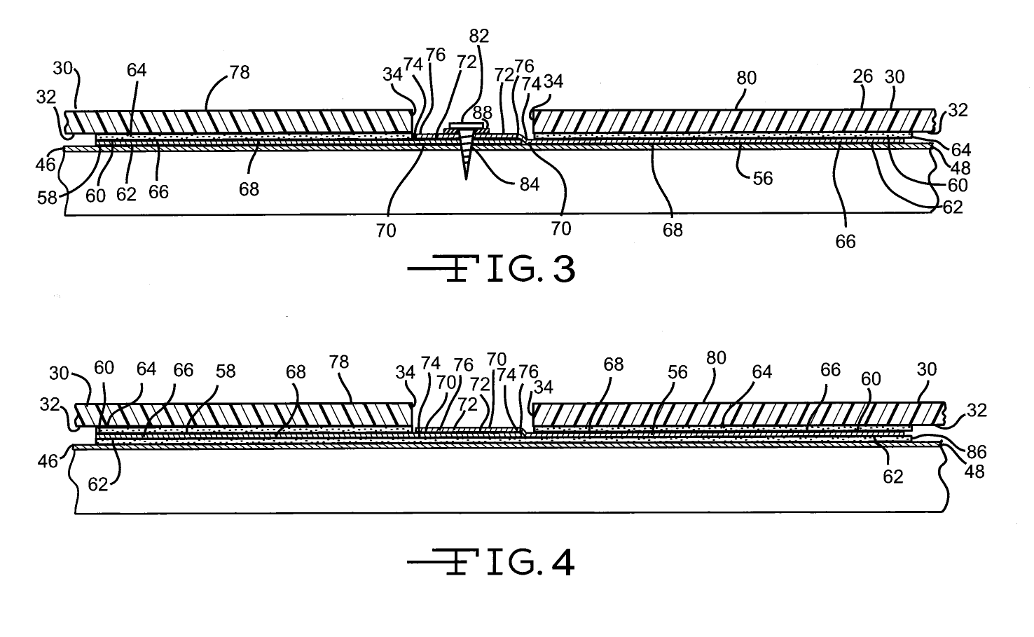

Apertures 84 in the support structure 46 may be problematic. Thus, it is also possible to practice the present invention without fasteners 82. As depicted in FIG. 4, in an alternative embodiment, fasteners 82 are not utilized to attach the support strips 56, 58 to the support structure 46. As shown, an adhesive layer 86 attaches the support strips 56, 58 to the support structure 46. It should be appreciated that the adhesive layer 86 may be substituted for the plurality of fasteners 82 in all of the embodiments of the PV array 20.

However, when fasteners 82 are utilized, sealing materials may be provided adjacent each fastener 82 and aperture 84 to prevent moisture ingress into the support structure 46. As shown in FIG. 3, a gasket 88 may be positioned between the fastener 82 and the support strips 56, 58. In another embodiment, shown best in FIG. 5, a weatherproofing strip 90 may be positioned above each fastener 82, the support strip flanges 72, and the support structure 46. Therefore, in a further embodiment shown in FIG. 6, a water resistant adhesive 92, such as a butyl adhesive, may be positioned between the support strips 56, 58 and the support structure 46 and a gasket 88 may be positioned between the fastener 82 and the support strips 56, 58. It should be appreciated that the sealing materials can be used in combination with each other. It should also be appreciated that the above-described sealing materials can be used with any of the embodiments of the present invention.

Additionally, in certain embodiments, weatherproof flashing may be added to the PV array 20 to prevent water from collecting beneath the PV modules 78, 80. In these embodiments, weatherproof flashing may be attached to the PV module edges 36, 38, 40, 42. For example, J channel (not depicted) or H channel (not depicted) could be attached to the PV modules 26 edges 36, 38, 40, 42. It should be appreciated that the sealing materials and weatherproof flashing can be used in combination with each other.

FIGS. 6-10 depict further embodiments of the flanges 72 that can be utilized in the first support strip 56 and second support strip 58 of the PV apparatuses 22, 24 of the present invention and in forming the PV array 20 of the present invention. As in the embodiments depicted in FIGS. 3-5, in the embodiments depicted in FIGS. 6-10 the second support strip 58 attached to the first photovoltaic module 78 is attached to the first support strip 56 attached to the second photovoltaic module 80. Furthermore, in certain embodiments, the second edge portion 70 of the second support strip 58 attached to the second edge portion 70 of the first support strip 56 are formed into shapes which are complimentary. It should be appreciated that in these embodiments, the PV array 20, the first and second PV apparatuses 22, 24, the PV modules 78, 80, the orientation of the first support strip 56 and second support strip 58 on the bottom surface 32 of the PV modules 78, 80 are as described, above, unless otherwise specified.

As shown in FIG. 6, the flanges 72 may be attached by an interlock 95 and overlap configuration.

In this embodiment, the flange 72 of the second support strip 58 attached to the bottom surface 32 of the first PV module 78 includes the first end 74, a horizontal member 94, a male connector 96, a tail portion 98, and the second end 76. The horizontal member 94 connects the first end 74 to the male connector 96. The male connector 96 may have a thickness or have a portion 100 which is twice the thickness of the first end 74 of the second support strip flange 72. The tail portion 98 is connected to the male connector 96 and the second end 76. The tail portion 98 may have a thickness which is substantially the same as the first end 74. The tail portion 98 and the first end 74 may be spaced apart and in a parallel relationship.

The flange 72 of the first support strip 56 attached to the bottom surface 32 of the second PV module 80 includes the first end 74, a female connector 102, a horizontal member 104, and the second end 76. The female connector 102 is connected to the first end 74 and the horizontal member 104. The female connector 102 may have a portion 106 which has a thickness that is twice the thickness of the first end 74 of first support strip flange 72. Additionally, the female connector 102 may be attached to the first end 74 and a concave portion 108. The horizontal member 104 may be connected to the female connector 102 or the concave portion 108 and the second end 76.

To form the PV array 20, the male connector 96 and female connector 102 may be selectively attached by positioning the male connector 96 within the female connector 102 so that the flanges interlock. As shown in FIG. 6, the interlock 95 has a thickness which is greater than the thickness of a first end 74 of one of the flanges 72. Specifically, the interlock 95 has a thickness which is five times thicker than the thickness of the first end 74 of the flange.

The strength of the interlock 95 may be further enhanced. In an embodiment, the strength of the interlock 95 may be further enhanced by a compression fit or friction between the male connector 96 and female connector 102. Additionally, the strength of the interlock 95 may be enhanced by contact between the tail portion 98 of the second support strip 58 and the horizontal member 104 of the first support strip 56. Also, as shown, fasteners 82 may be placed through the interlock 95 and into the support structure 46 to fixedly position the PV array 20 above the support structure 46 and enhance the strength of the interlock 95.

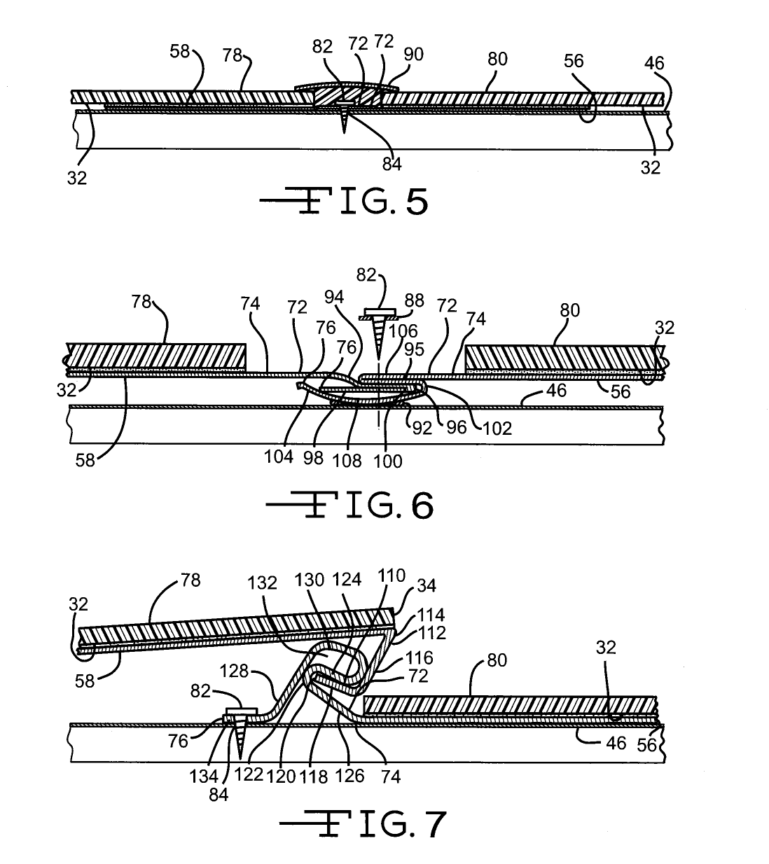

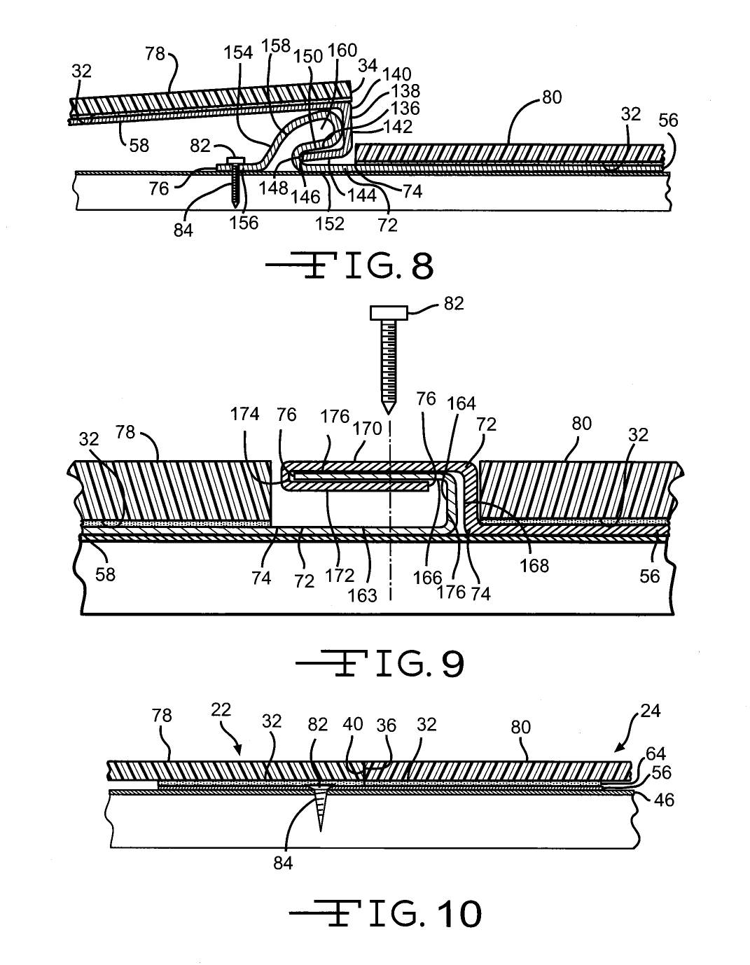

FIG. 7 depicts another embodiment of the present invention having an interlock 110 and overlap configuration.

In this embodiment, the second support strip 58 attached to the bottom surface 32 of the first PV module 78 includes a flange 112 having a first end 114, a horizontal member 116, a male connector 118, and a second end 120. In this embodiment, the flange 112 does not extend beyond the first PV module perimeter 34. The horizontal member 116 is attached to the first end 114 and the male connector 118. The male connector 118 is also attached to the second end 120. The horizontal member 116 and the male connector 118 may be connected in an orthogonal relationship or at a slightly acute angle.

The flange 72 of the first support strip 56 attached to the bottom surface 32 of the second PV module 80 includes the first end 74, a female connector 122, and a hook-like lip 124, and the second end 76. The first end 74 is attached to the female connector 122, the female connector 122 is attached to the hook-like lip 124, and the hook-like lip 124 is attached to the second end 76. Additionally, a first leg member 126 and a second leg member 128 may be provided.

In an embodiment, the first leg member 126 attaches the first end 74 to the female connector 122. Additionally, the second leg member 128 attaches the hook-like lip 124 to the second end 76. Also, the first leg member 126 and the second leg member 128 are in an orthogonal relationship. In this configuration, an inner wall 130 is provided which forms an aperture 132. Fasteners 82 may be provided through the second leg member 128 to attach and fixedly position the PV array 20 above the support structure 46. Thus, a portion 134 of the second leg member 128 may be in a parallel relationship with the surface of the support structure 46.

To form the PV array 20, the male connector 118 and female connector 122 may be selectively attached by positioning the male connector 118 within the female connector 122 so that the flanges 72, 112 form the interlock 110. In an embodiment, the interlock 110 between the flanges 72, 112 may be strengthened by friction between the male connector 118 and female connector 122.

The interlock 110 may be strengthened by the combined thickness of the male connector 118 and the female connector 122. In this embodiment, the interlock 110 is thicker than the first end 74 of the flange 72. Specifically, the interlock 110 has a thickness which is two times thicker than the thickness of the first end 74 of the flange 72. Additionally, the strength of the interlock 110 may be enhanced by the inner wall 130.

FIG. 8 depicts another embodiment of the present invention having an interlock 136 and overlap configuration.

In this embodiment, the second support strip 58 attached to the bottom surface 32 of the first PV module 78 includes a flange 138 having a first end 140, a horizontal member 142, a male connector 144, and a second end 146. In this embodiment, the flange 138 does not extend beyond the first PV module perimeter 34. The horizontal member 116 is attached to the first end 114 and the male connector 144. The male connector 144 is also attached to the second end 146. The horizontal member 142 and the male connector 144 may be connected in an orthogonal relationship.

In this embodiment, the flange 72 of the first support strip 56 attached to the bottom surface 32 of the second PV module 80 includes the first end 74, a female connector 148, and a hook-like lip 150, and the second end 76. The first end 74 is attached to the female connector 148, the female connector 148 is attached to the hook-like lip 150, and the hook-like lip 150 is attached to the second end 76. Additionally, a first leg member 152 and a second leg member 154 may be provided.

In an embodiment, the first leg member 152 attaches the first end 74 to the female connector 148. Additionally, the second leg member 154 attaches the hook-like lip 150 to the second end 76. In this embodiment, the first leg member 126 and a portion 156 of the second leg member 154 are in a concentric relationship. In this configuration, an inner wall 158 is provided which forms a partially closed aperture 160. Fasteners 82 may be provided through the second leg member 154 to attach and fixedly position the PV array 20 above the support structure 46. Thus, portion 156 of the second leg member 154 may be in a parallel relationship with the surface of the support structure 46.

To form the PV array 20, the male connector 144 and female connector 148 may be selectively attached by positioning the male connector 144 within the female connector 148 so that the flanges 72, 138 to form the interlock 136. In an embodiment, the interlock 136 between the flanges 72, 138 may be strengthened by friction between the male connector 144 and female connector 148.

Also, the interlock 138 may be strengthened by the combined thickness of the male connector 144 and the female connector 148. In this embodiment, the interlock 138 has a thickness which is greater than the thickness of a first end 74 of one of the flanges 72. Specifically, the interlock 138 is two times thicker than the thickness of the first end 74 of the flange 72. Additionally, the strength of the interlock 110 may be enhanced by the partially closed aperture 160.

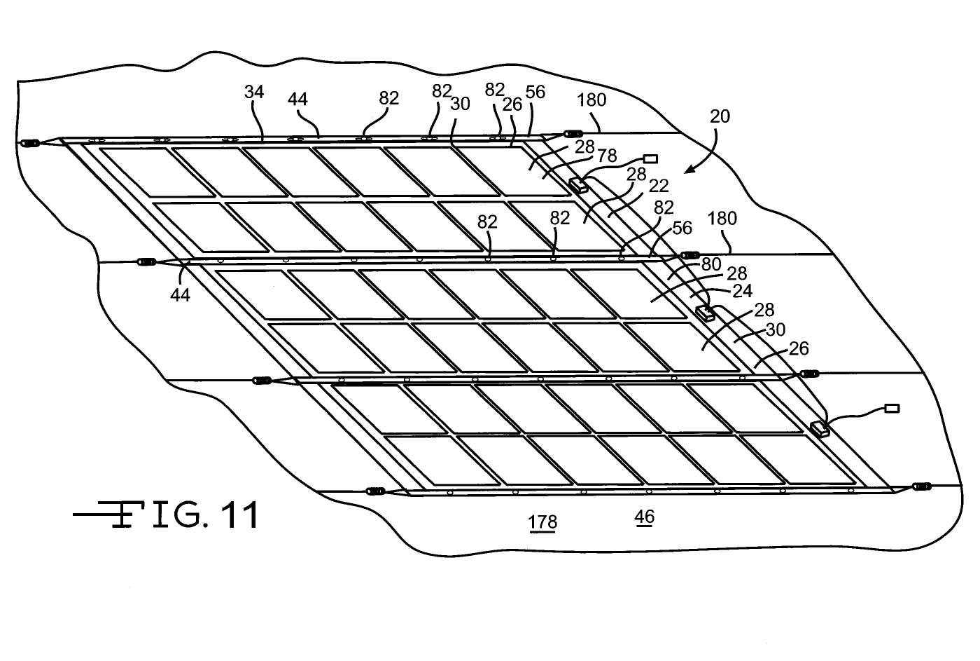

FIG. 9 depicts another embodiment of the present invention having an interlock 162 and overlap configuration.

As shown in FIG. 9, in this embodiment the flange 72 of the second support strip 58 attached to the bottom surface 32 of the first PV module 78 includes the first end 74, a leg member 163, a horizontal member 164, a male connector 166, and the second end 76. The leg member 163 connects the first end 74 and the horizontal member 164. The horizontal member 164 connects the leg member 163 to the male connector 166. The male connector 166 and the leg member 164 may be in a parallel relationship.

Additionally, the flange 72 of the first support strip 56 attached to the bottom surface 32 of the second PV module 80 includes the first end 74, a horizontal member 168, a pair of leg members 170, 172, a female connector 174 and the second end 76. The first end 74 is attached to the horizontal member 168. The horizontal member is attached to the leg member 170. The female connector 174 is attached to the pair of leg members 170, 172 and the leg member 172 is attached to the second end 76.

Additionally, the first support strip and the second support strip flanges 72 may further include a channel 176. Each channel 170 is located between the first end 74 and the second end 76. The channels 176 may be formed into several shapes. For example, the channels 176 may have a C-shape, J-shape, U-shape, V-shape, or a combination of shapes thereof. Also, those skilled in the art would appreciate that other channel shapes may be utilized to practice the present invention.

To form the PV array 20, the channels 176 are positioned so that the male connector 166 and female connector 174 are selectively attached so that the flanges 72 form the interlock 162. In an embodiment, the interlock 162 between the flanges 72 may be strengthened by a compression fit or friction between the male connector 166 and female connector 174.

Also, the interlock 162 may be strengthened by the combined thickness of the male connector 166 and the female connector 174. In this embodiment, the interlock 166 has a thickness which is greater than the thickness of a first end 74 of one of the flanges 72. Specifically, the interlock 166 is three times thicker than the thickness of the first end 74 of the flange 72.

Referring now to FIGS. 2 and 10, which depict an embodiment of the PV array 20, wherein the first and second PV apparatuses 22, 24 comprise only a first support strip 56. As shown, the PV array 20 comprises the first and the second PV apparatuses 22, 24. The first PV apparatus 22 comprises the first PV module 78 and the first support strip 56. The first support strip 56 of the first PV apparatus 22 is attached to the bottom surface 32 of the first PV module 78. As best seen in FIG. 10, the second PV apparatus 24 comprises the second PV module 80 and the first support strip 56. The first support strip 56 of the second PV apparatus 24 is attached to the bottom surface 32 of the second PV module 80 by an adhesive 64.

In this embodiment, the first support strips 56 are attached to the support structure 46 in a substantially parallel and spaced apart manner. As shown in FIG. 2, the first support strips 56 are attached to the support structure 46 by a plurality of fasteners 82. As mentioned above, in an embodiment the support structure 46 is a corrugated rooftop 48. The corrugated rooftop 48 can be of any of the configurations of corrugated rooftop structures previously described.

The first PV module 78 may be attached to the first support strip 56 of the second PV apparatus 24 by the adhesive 64. The adhesive 64 that attaches the first PV module 78 to the first support strip 56 of the second PV apparatus 24 is positioned above the fastener 82. It should be appreciated that the various adhesives described, above, can be used in the embodiment depicted in FIGS. 2 and 10.

As shown in FIGS. 2 and 10, an edge 40 of the first PV module 78 abuts an edge 36 of the second PV module 80. However, a small space (not depicted) may be provided between the edges 36, 40 of the PV modules 78, 80. In an alternative embodiment, the PV modules 78, 80 may be in a shingled configuration (not depicted). In this embodiment, the edge 40 of the first PV module 78 is positioned above the edge 36 of the second PV module 80.

In another embodiment advantageous for field installation, the adhesive layer 64 that attaches the first PV module 78 to the first support strip 56 of the second PV apparatus 24 may be protected by a release layer (not depicted) prior to forming the PV array 20. In this embodiment, the release layer 46 covers the adhesive layer which allows for selective attachment during installation. Several embodiments of the release layer 46 are possible for use with the present invention. In an embodiment, the release layer 46 comprises plastic. A preferred plastic is polyester. In another embodiment, the release layer 46 comprises a body of paper coated with a low surface energy material.

During installation of the PV array 20, the release layer can be removed and the first PV module 78 can be attached to the first support strip 56 of the second PV apparatus 24. In a similar manner, the second PV apparatus 24 can be attached to other PV apparatuses to form the PV array 20.

Also, as stated above, the support structure 46 of the present invention may be earthen. FIG. 11 depicts the PV array 20 of FIG. 1 attached to an earthen surface 178. It should be appreciated that all of the above-described embodiments could be utilized when the support structure 46 is earthen. Earthen surfaces which are particularly advantageous for use with the present invention are landfill caps. In certain embodiments, the earthen surface 178 may be uneven or graded to provide a slope.

As with the other embodiments of the present invention, the PV array 20 is positioned above and fixedly attached to the support structure 46, i.e. earthen surface 178. As such, fasteners 82, as described above, may be utilized to attach the support strips 56, 58 to the earthen surface 178. As stated, mounting rails may also be utilized in this embodiment to provide additional support. Preferably, the mounting rails are attached to the earthen surface 178 and orthogonally with respect to the support strips 56, 58.

FIG. 12 shows a portion of the first PV apparatus first support strip 56 with the PV module 78 removed to depict how the PV array 20 may be additionally attached to the earthen surface 178. As shown in FIG. 12, a cable 180, a turnbuckle 182, and an anchor 184 or stake may be utilized in practicing this embodiment. On one end the cable 180 is attached to the first support strip 56 by grommets 186 and on the other end to the turnbuckle 182. The turnbuckle 182 is attached to the anchor 184 and the anchor penetrates the earthen surface 178. It should be appreciated that the cable 180 can be attached to the second support strip 58. It should also be appreciated that cables 180, turnbuckles 182, and anchors 184 could also be used with the other embodiments of the present invention.

In accordance with the provisions of the patent statutes, the present invention has been disclosed in what are considered to represent its preferred embodiments. However, it should be noted that the invention can be practiced otherwise than as specifically illustrated and described without departing from its spirit or scope.

What we claim is:

1. A photovoltaic apparatus, comprising:
a photovoltaic module;
at least one support strip attached to a bottom surface of the photovoltaic module, each support strip comprising a first edge portion, a center portion, and a second edge portion, wherein the second edge portion includes a flange having a first end and a second end.

2. A photovoltaic apparatus of claim 1, wherein the at least one support strip is composed of metal or rigid PVC and is attached to a bottom surface of the photovoltaic module with an adhesive.

3. The photovoltaic apparatus of claim 1, wherein the at least one support strip comprises a first support strip and a second support strip attached to opposite sides of and spaced apart on the bottom surface of the photovoltaic module.

4. The photovoltaic apparatus of claim 3, wherein the flange is substantially planar.

5. The photovoltaic apparatus of claim 3, wherein the flange further includes either a male or a female connector and wherein the connector has a portion which is twice the thickness of the first end.

6. The photovoltaic apparatus of claim 3, wherein the second support strip flange further includes a horizontal member attached to the first end and a male connector.

7. The photovoltaic apparatus of claim 3, wherein the first support strip flange further includes a female connector wherein the female connector is attached to the first end and a concave portion.

8. The photovoltaic apparatus of claim 3, wherein either the first support strip flange or the second support strip flange further includes a channel attached to the first end and the second end, wherein the channel has a C-shape, J-shape, U-shape, V-shape, or a combination thereof.

9. The photovoltaic apparatus of claim 3, wherein the first support strip flange includes a hook-like lip attached to the first end.

10. The photovoltaic apparatus of claim 3, wherein the second support strip flange includes a male connector attached to the first end and a tail portion attached to the male connector and the second end, wherein the male connector is twice the thickness of the first end.

11. The photovoltaic apparatus of claim 10, wherein the first support strip flange further includes an inner wall which is configured to form an aperture.

12. The photovoltaic apparatus of claim 12, wherein the first support strip flange further includes a leg member attached to the hook-like lip and either the first end or the second end.

13. A photovoltaic array, comprising:
a first flexible photovoltaic module;
a first support strip and a second support strip attached to opposite sides of and spaced apart on a bottom surface of the first flexible photovoltaic module, the support strips comprising a first edge portion, a center portion, and a second edge portion;
a second flexible photovoltaic module;
a first support strip and a second support strip attached to opposite sides of and spaced apart on a bottom surface of the second flexible photovoltaic module, the support strips comprising a first edge portion, a center portion, and a second edge portion; and
wherein the second support strip attached to the first flexible photovoltaic module is attached to the first support strip attached to the second flexible photovoltaic module.

14. The photovoltaic array of claim 14, wherein the second edge portion of the second support strip attached to the second edge portion of the first support strip are formed into shapes which are complimentary.

15. The photovoltaic array of claim 14, wherein the second edge portion of the second support strip attached to the second edge portion of the first support strip each comprise a flange which overlaps the other flange.

16. The photovoltaic array of claim 14, wherein the attachment of the second support strip to the first support strip is selective.

17. The photovoltaic array of claim 14, wherein the attachment of the second edge portion of the second support strip to the second edge portion of the first support strip forms an interlock.

18. The photovoltaic array of claim 14, wherein the support strips are rigid.

19. A photovoltaic array of claim 14 attached to a support structure, wherein the support structure is a corrugated rooftop.
